(19) United States
(12) Patent Application Publication
(10) Pub. No.: US 2025/0194184 A1
(43) Pub. Date: Jun. 12, 2025

(54) Power Semiconductor Device and Method of Producing a Power Semiconductor Device

(71) Applicant: Infineon Technologies AG, Neubiberg (DE)

(72) Inventors: Alexander Philippou, München (DE); Thorsten Arnold, Jesenwang (DE); Steffen Schmidt, Dresden (DE); Franz Josef Niedernostheide, Hagen a.T.W. (DE)

(21) Appl. No.: 18/967,710

(22) Filed: Dec. 4, 2024

(30) Foreign Application Priority Data
Dec. 8, 2023 (DE) 102023212431.9

(51) Int. Cl. H10D 62/10; H01L 21/762

(52) U.S. Cl. CPC H10D 62/127; H01L 21/76232; H10D 62/112

(57) ABSTRACT

A power semiconductor device includes: a semiconductor body with a drift region of a first conductivity type and load terminals at opposite first and second sides of the semiconductor body. The power semiconductor device is configured to conduct a forward load current between the load terminals. A trench grid structure extending from the first side into the semiconductor body includes a plurality of macro cells. Each macro cell includes at least one first type micro cell configured for the forward load current conduction and a number of second type micro cells not configured for the forward load current conduction. Each micro cell is laterally confined by a respective portion of the trench grid structure. In each macro cell, the number of the second type micro cells is equal to or greater than the number of first type micro cells.

### TECHNICAL FIELD

This specification refers to embodiments of a power semiconductor device and to embodiments of a method of producing a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

Regarding IGBTs, a trend can be observed of further reducing the pitch and subsequently mesa width in a typical stripe cell design, called micro pattern trench (MPT) IGBTs, which leads to lower V_{ce,sat} and increased hole confinement. While doing so, several approaches are implemented to recover dV/dt and/or dI/dt control (e.g. n-doped areas in the mesas, or p-doped areas at the trench bottom). This is supported by elaborate contact schemes, e.g., by putting trenches on gate or source potential, and placing or leaving out contact grooves in the different mesas.

### SUMMARY

According to an embodiment, a power semiconductor device comprises: a semiconductor body with a drift region of a first conductivity type; a first load terminal at a first side of the semiconductor body; a second load terminal at a second side of the semiconductor body opposite to the first side, wherein the power semiconductor device is configured to conduct a forward load current between the first load terminal and the second load terminal; a trench grid structure extending from the first side into the semiconductor body, wherein the trench grid structure comprises a plurality of macro cells, each macro cell comprising at least one first type micro cell configured for the forward load current conduction and a number of second type micro cells not configured for the forward load current conduction. Each of the first type micro cells and the second type micro cells is laterally confined by a respective portion of the trench grid structure. In each of the macro cells, the number of the second type micro cells is equal to or greater than the number of first type micro cells.

According to another embodiment, a method of producing a power semiconductor device comprises forming the following components: a semiconductor body with a drift region of a first conductivity type; a first load terminal at a first side of the semiconductor body; a second load terminal at a second side of the semiconductor body opposite to the first side, wherein the power semiconductor device is configured to conduct a forward load current between the first load terminal and the second load terminal; a trench grid structure extending from the first side into the semiconductor body, wherein the trench grid structure comprises a plurality of macro cells, each macro cell comprising at least one first type micro cell configured for the forward load current conduction and a number of second type micro cells not configured for the forward load current conduction. Each of the first type micro cells and the second type micro cells is laterally confined by a respective portion of the trench grid structure. In each of the macro cells, the number of the second type micro cells is equal to or greater than the number of first type micro cells.

In accordance with some embodiments described herein, herein, a simple and cost effective cell design is proposed based on a simple square cell, which maintains important features of the MPT technology. E.g., the new cell designs exceed previous solutions in maintaining a good dV/dt and dI/dt control.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a horizontal projection of a power semiconductor device in accordance with one or more embodiments;

FIG. 2 schematically and exemplarily illustrates a horizontal projection of a power semiconductor device in accordance with one or more embodiments;

FIG. 3(A) schematically and exemplarily illustrates a perspective projection of a power semiconductor device in accordance with one or more embodiments;

FIG. 3(B) schematically and exemplarily illustrates a horizontal projection of a power semiconductor device in accordance with one or more embodiments;

FIG. 4 schematically and exemplarily illustrates a perspective projection of a power semiconductor device in accordance with one or more embodiments;

FIG. 5 schematically and exemplarily illustrates a perspective projection of a power semiconductor device in accordance with one or more embodiments;

FIG. 6 schematically and exemplarily illustrates a horizontal cross-section of a power semiconductor device in accordance with one or more embodiments;

FIG. 7 schematically and exemplarily illustrates a vertical cross-section of a power semiconductor device in accordance with one or more embodiments;

FIG. 8(A) schematically and exemplarily illustrates a horizontal cross-section of a power semiconductor device in accordance with one or more embodiments;

FIG. 8(B) schematically and exemplarily illustrates a perspective projection of a power semiconductor device in accordance with one or more embodiments; and

FIG. 9 schematically and exemplarily illustrates a horizontal cross-section of a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip, e.g., exhibiting a rectangular cell configuration, a square cell configuration, or a hexagonal cell configuration and can be configured to be employed as a power component in a low-, medium- and/or high voltage application.

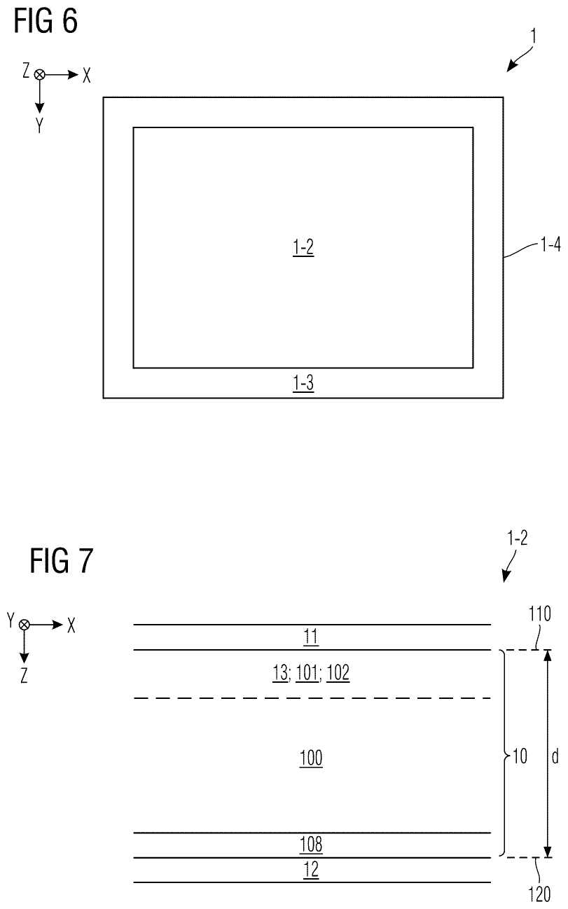

Referring first to FIGS. 6 and 7, a possible general configuration of the power semiconductor device 1 shall be explained:

The power semiconductor device 1, herein also referred to as “device”, comprises, e.g., in a single chip, a semiconductor body 10 configured to conduct a load current between a first load terminal 11 at a first side 110 of the semiconductor body 10 and a second load terminal 12 at a second side 120 of the semiconductor body 10.

The first side 110 and the second side 120 may be arranged opposite of each other. E.g., the first side 110 is a front side of the device 1 and the second side 120 is a back side of the device 1. Accordingly, the device 1 may exhibit a vertical configuration according to which the load current within the device 1 follows a path in parallel to the vertical direction Z. The semiconductor body 10 may be sandwiched between the first load terminal 11 and the second load terminal 12 and exhibit a vertical extension d, e.g., in the range of 50 μm to 700 μm, depending on the designated maximal blocking voltage.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities (e.g., said maximal blocking voltage) of the device 1.

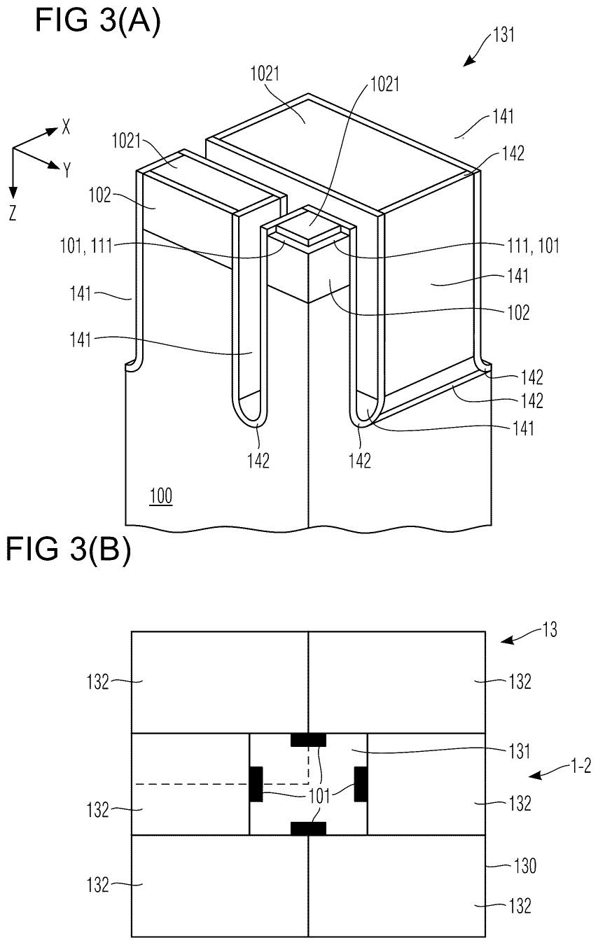

The device 1 further comprises a trench grid structure 13 that extends from the first side 110 into the semiconductor body 10 towards the second side 120, e.g., along the vertical direction Z. The trench grid structure 13 will be described in greater detail below. The trench grid structure 13 can comprise at least one trench control electrode 141 (cf. FIG. 3) electrically insulated from the first load terminal 11 and configured to receive a control signal. To this end, the trench control electrode 141 can be electrically connected to a control terminal (not illustrated) of the device 1, in accordance with an embodiment.

At the first side 110, the semiconductor body 10 further comprises a semiconductor body region 102 of the second conductivity type electrically connected to the first load terminal 11 and a semiconductor source region 101 of the first conductivity type electrically connected to the first load terminal 11, wherein the semiconductor source region 101 is isolated from the drift region 100 by at least the semiconductor body region 102. The trench control electrode 141 of the trench grid structure 13 can be configured to induce, upon being subject with a corresponding ON-control signal, an inversion channel in the semiconductor body region 102. This process may set the device 1 into the forward conducting state. The trench control electrode 141 can further be configured to cut off, upon being subject with a corresponding OFF-control signal, said inversion channel in the semiconductor body region 102, which can set the device 1 into the forward blocking state.

A doped region 108 of the semiconductor body 10 below the drift region 100 adjoining the second load terminal 12 at the second side 120 can be configured in accordance with the designated characteristic of the device 1. E.g., the doped region 108 can be an emitter region of the second conductivity type, if the device 1 shall exhibit an IGBT configuration. The emitter region is arranged in contact with the second load terminal 12.

In addition, a field stop region (not illustrated) of the first conductivity type can be provided between the drift region 100 and the second load terminal 12, wherein the field stop region exhibits a greater dopant concentration than the drift region 100.

If the device 1 shall exhibit a MOSFET configuration, the emitter region is omitted such that the field stop region (or another highly doped region of the first conductivity type) would adjoin the second load terminal 12. If the device 1 shall exhibit an RC IGBT configuration, the emitter region may exhibit subsections of the first conductivity type, as it is known to the skilled person.

The above-described components of the power semiconductor device 1 are arranged in the active region 1-2 of the device 1 (cf. FIG. 6), which is surrounded by an edge termination region 1-3. In the active region 1-2, the trench grid structure (13) may form a cell field, which will be explained further below. The edge termination region 1-3 is typically not employed for load current conduction, as it is known to the skilled person. The edge termination region 1-3 is terminated by the chip edge 1-4.

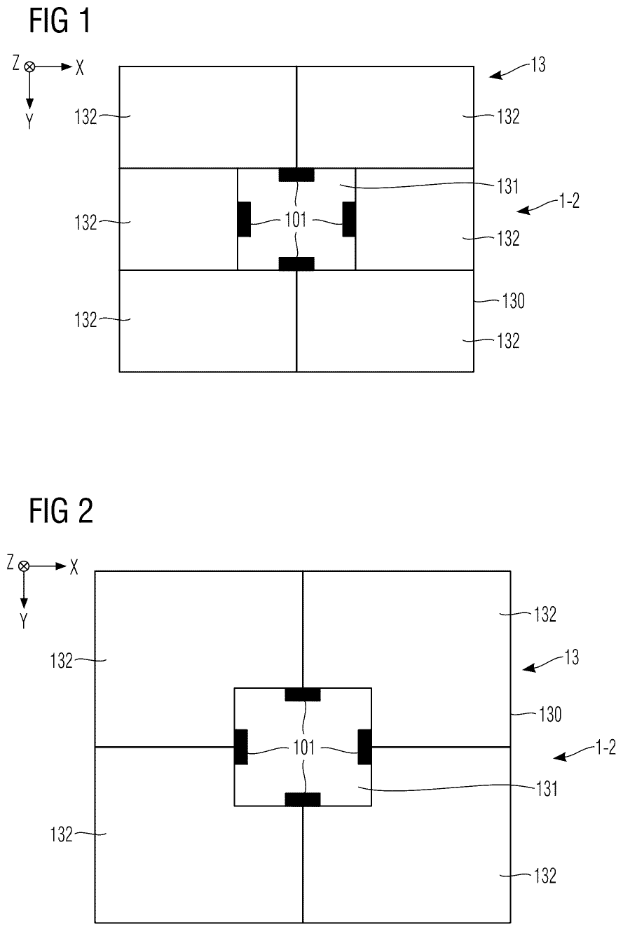

FIGS. 1 and 2 both schematically and exemplarily illustrate a horizontal projection of the power semiconductor device in accordance with one or more embodiments. Illustrated are examples of the trench grid structure 13 that extends from the first side 110 into the semiconductor body 10. The trench grid structure 13 comprises a plurality of macro cells 130, one of which is illustrated in FIG. 1 and FIG. 2, respectively.

Each macro cell 130 comprises at least one first type micro cell 131 configured for the forward load current conduction and a number of second type micro cells 132 not configured for the forward load current conduction. The number of second type micro cells 132 may amount to zero, one or more than one. In these second type micro cells, there is no forward load current conduction. For example, to this end, the semiconductor source regions 101 are only implemented in the first type micro cells 131, but not in the second type micro cells, in accordance with an embodiment. Furthermore, each of first type micro cells 131 is electrically connected with the first load terminal 11, e.g., based on an ohmic contact, in accordance with an embodiment. The second type micro cells 132 are not necessarily electrically connected to the first load terminal 11.

In an embodiment, none of the second type micro cells 132 is electrically connected to the first load terminal 11. E.g., this variant can be appropriate in case the device 1 exhibits an IGBT configuration.

In an embodiment, some or all of the second type micro cells 132 are also electrically connected to the first load terminal 11. E.g., this variant can be appropriate in case the device 1 exhibits an RC-IGBT configuration. Still, in this embodiment, none of the second type micro cells 132 comprise a semiconductor source region 101.

As illustrated in both FIG. 1 and FIG. 2, each of the first type micro cells 131 and the second type micro cells 132 is laterally confined by a respective portion of the trench grid structure 13. Furthermore, in each of the macro cells 130, the number of the second type micro cells 132, if implemented, is equal to or greater than the number of first type micro cells 131.

In an embodiment, each of the first type micro cells 131 exhibits a rectangular horizontal cross-sectional area with an aspect ratio among the side faces of at most 2:1. For example, each of the first type micro cells 131 exhibits a quadratic horizontal cross-sectional area. For example, each of the first type micro cells 131 exhibits a rectangular horizontal cross-sectional area with an aspect ratio among the side faces of greater than 1:1 (such that the first type micro cells 131 is not quadratic) and at most 2:1. Likewise, each of the second type micro cells 132 may exhibit a rectangular horizontal cross-sectional area with an aspect ratio among the side faces of at most 2:1. For example, each of the second type micro cells 132 exhibits a quadratic horizontal cross-sectional area. For example, each of the second type micro cells 132 exhibits a rectangular horizontal cross-sectional area with an aspect ratio among the side faces of greater than 1:1 (such that the second type micro cells 131 is not quadratic) and at most 2:1.

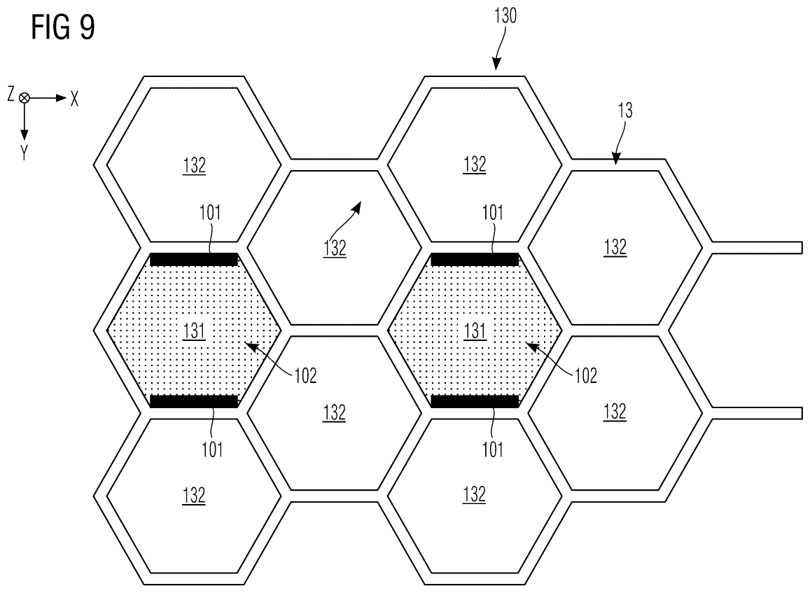

Referring to FIG. 9, in an embodiment, each of the first type macro cells 131 and the second type macro cells 132 exhibit the same size and shape, namely a hexagonal shape. The first type macro cells 131 and the second type macro cells 132 may be arranged in accordance with a hexagonal packing within the active region 1-2. For example, each side of each hexagon may exhibit a length aₕₑₓ within the range of 2 μm to 4 μm, such as 3 μm.

Still referring to FIG. 9, it may be ensured, in accordance with an embodiment, the source regions 101 only extend along sections of the trench structure 13 that exhibit the same orientation, such as along the first lateral direction X, as illustrated in FIG. 9. Thereby, a variation of the threshold voltage Vth of the device 1 due to eventual variations of the thickness of the trench insulator 142 can be reduced or even avoided. This variant may also be provided for the embodiments illustrated in, e.g., FIG. 1 and FIG. 2, in contrast to the exemplary illustrations there.

Furthermore, referring back to both FIG. 1 and FIG. 2, each of the macro cells 130, each of the first type micro cells 131 and each of the second type micro cells 132 exhibits, in accordance with an embodiment, at least a substantially rectangular horizontal cross-sectional area. E.g., the second type micro cells 132 in FIG. 1 have rectangular horizontal cross-sectional area, whereas the second type micro cells 132 in FIG. 2 have a substantially rectangular horizontal cross-sectional area, where small subsections are “carved out” by the first type micro cell 131.

For example, wherein each of the first type micro cells 131 (e.g., having for example a rectangular horizontal cross-section or a quadratic horizontal cross-section) exhibits a horizontal cross-sectional area of smaller than 5 μm*5 μm, smaller than 4 μm*4 μm, smaller than 3 μm*3 μm, or even smaller than 2 μm*2 μm. Likewise, each of the second type micro cells 132 (e.g., having for example a rectangular horizontal cross-section or a quadratic horizontal cross-section) exhibits a horizontal cross-sectional area of smaller than 5 μm*5 μm, smaller than 4 μm*4 μm, smaller than 3 μm*3 μm, or even smaller than 2 μm*2 μm.

Furthermore, in accordance with an embodiment, each portion of the grid structure 13 that laterally confines either one of the first type micro cells 131 and/or one of the of the second type micro cells 132 and that extends continuously along either first lateral direction X or the second lateral direction Y until adjoining another portion of the grid structure 13 extending perpendicular thereto is shorter than 10 μm.

In an embodiment, in each of the macro cells 130, the at least one first type micro cell 131 is surrounded by the second type micro cells 132. E.g., as best illustrated in FIGS. 1, 2 and 8, it may be provided that, in each of the macro cells 130, the at least one first type micro cell 131 is surrounded only by the second type micro cells 132.

In a further embodiment, in each of the macro cells 130, the at least one first type micro cell 131 exhibits a horizontal cross-sectional area smaller than each of the horizontal cross-sectional areas of the second type micro cells 132. In another embodiment, in each of the macro cells 130, the at least one first type micro cell 131 exhibits a horizontal cross-sectional area equal to the horizontal cross-sectional area of at least one of the second type micro cells 132; e.g., each of the first type micro cells 131 and the second type micro cells 132 exhibit the same size. In yet another embodiment, the at least one first type micro cell 131 exhibits a horizontal cross-sectional area greater than each of the horizontal cross-sectional areas of the second type micro cells 132.

In another embodiment, in each of the macro cells 130, the ratio of the number of the second type micro cells 132 to the number of first type micro cells 131 is at least 3/1. E.g., each macro cell 130 includes a first number of first type micro cells 131 and second number of second type micro cells 132, wherein the second number is at least three times the first number.

With respect to FIGS. 3 (A) and (B), further optional aspects of the trench grid structure 13 shall be explained. FIG. 3(B) corresponds with FIG. 2 explained above, and FIG. 3(A) illustrates an associated perspective view of a part of FIG. 3(B) indicated by the dashed line in FIG. 3(A).

Accordingly, the trench grid structure 13 may house said trench control electrode 141 and a trench insulator 142 electrically insulating the trench control electrode 141 from the semiconductor body 10. In an embodiment, at least each first type micro cell 131 is surrounded by a respective portion of the grid structure 13. E.g., at least each first type micro cell 131 is surrounded by a portion of the trench control electrode 141. As explained above with respect to FIGS. 1 and 2, the trench control electrode 141 is configured to induce, upon being subjected with a control signal, an inversion channel within each of the first type micro cells 131.

In an embodiment, it may even be provided that the trench grid structure 13 exclusively houses the trench control electrode 141, wherein, e.g., the trench control electrode 141 forms an uninterrupted electrically conductive structure within the trench grid structure 13. For example, the design proposed herein allows avoiding the implementation of source trenches or other trench types, which in turn facilitates the contacting scheme.

Further, each of first type micro cells 131 can be electrically connected with the first load terminal 11, e.g., based on an ohmic contact, such as contact plug 111 that may exhibit a closed course following essentially an outer circumference of the respective first type micro cell 131, as schematically illustrated in FIG. 3. Instead of the contact plug 111, a flat contact may be employed.

Each of first type micro cells 131 may further include said semiconductor source region 101 of the first conductivity type and said semiconductor body region 102 of the second conductivity type. The semiconductor body region 102 isolates the semiconductor source region 101 from the drift region 100, and wherein both the semiconductor source region 101 and the semiconductor body region 102 are electrically connected to the first load terminal 11, e.g., based on said contact plug 111.

The doping and the size of the source region 101 can be adjusted according to the designated characteristic of the device. E.g., as for the contact plug 111, is may also be provided that the source region 101 also exhibits a closed course following essentially the outer circumference of the respective first type micro cell 131, unlike only about 50% of it, as schematically illustrated in FIG. 3. Then, the first type micro cell 131 would be “surrounded” by the semiconductor source region 101.

The body region 102 may extend into both the first and second type micro cells 131, 132.

Both the semiconductor source region 101 and the semiconductor body region 102 are electrically connected to the first load terminal 11.

For example, at the first side 110, the body region 102 exhibits a highly doped subportion 1021 to improve the electrical contact to the first load terminal 11. In an embodiment, it is further ensured that the body region 102 exhibits, within the macro cells 130, a depth of less than 50% of the depth of the trench grid structure 13. E.g., it is ensured that the bottom of the trench grid structure 13 terminates in the drift region 100 or a differently doped subsection, e.g., a barrier region or the like, thereof.

Furthermore, as illustrated, the trench grid structure 13 exhibits a constant depth along a vertical direction Z, said constant depth locally varying by less than 1 μm, in accordance with an embodiment. Said variation can also be significantly less than 1 μm.

Portions of the trench grid structure 13 are filled with an isolating material instead of electrode material used for forming the trench control electrode 141, e.g., so as to adjust a total gate charge.

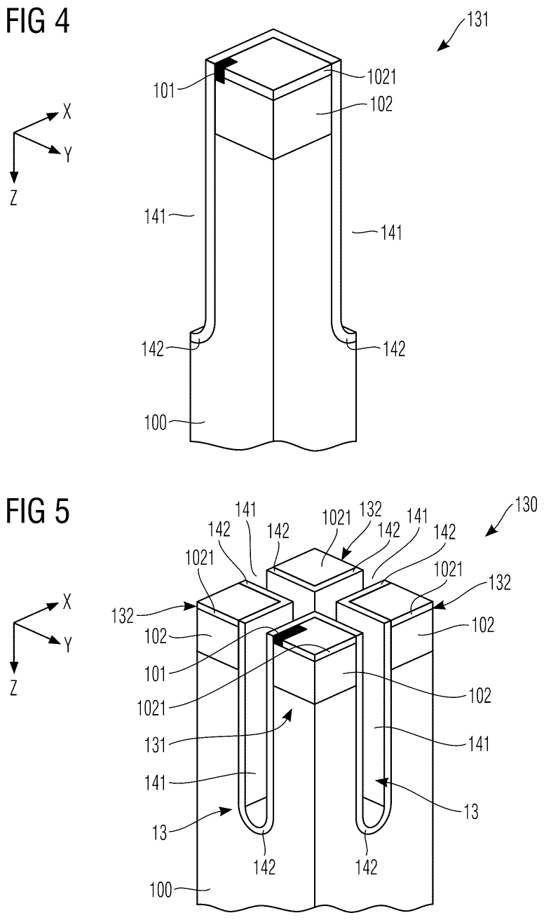

FIG. 4 shows a slightly modified version of the first type micro cell 131. The first type micro cell 131 also exhibits a quadratic horizontal cross-sectional area, wherein the semiconductor source region 101 only extends in between two of the four corners (of which only one is illustrated in FIG. 4). In this embodiment, the macro cell 130 does not comprise any second type micro cell 132; accordingly, due to the comparatively high density of first type micro cells 131, the size of the source region 101 is kept comparatively small in each first type micro cell 131. According to other embodiments, regions on the semiconductor device 10 exists which are completely build up by first type micro cells 131 and separated from each other by regions consisting of second type micro cells 132.

In an embodiment, in each of the first type micro cells 131, the ratio between the lateral length of the source region 101 and the horizontal cross-section area of the first type micro cell 131 is less than ⅕ μm.

FIG. 5 shows a variant of the macro cell 130, including three second type micro cells 132 and one first type micro cell 131, each of which exhibit a quadratic horizontal cross-sectional area and separated from each other based on the trench grid structure 13. E.g., in this variant, the size of the source region 101 in each first type micro cell 131 is increased compared to the variant of FIG. 4.

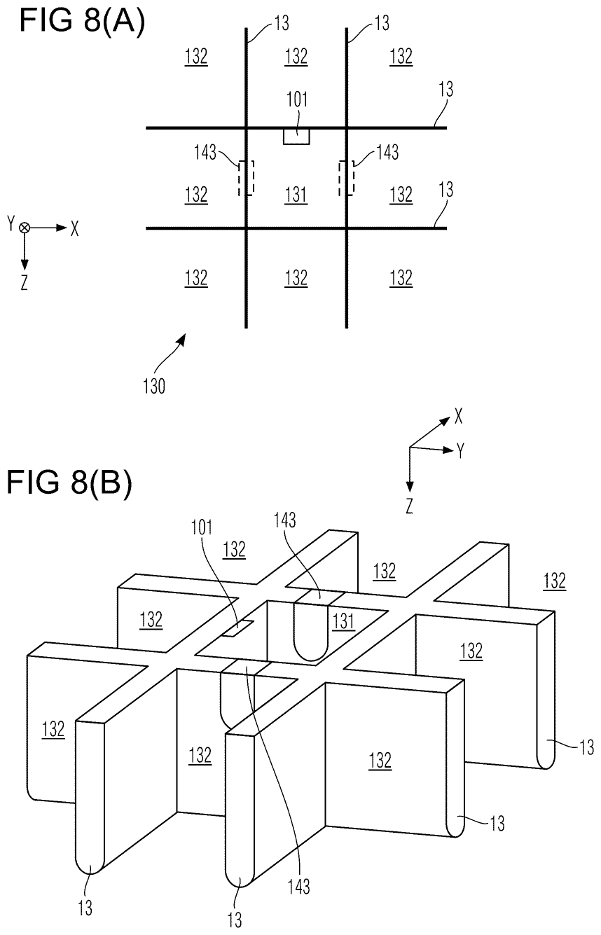

FIGS. 8(A) and (B) shows a yet further variant of the macro cell 130, including eight second type micro cells 132 and one first type micro cell 131, each of which exhibit a rectangular/quadratic horizontal cross-sectional area and separated from each other based on the trench grid structure 13. E.g., in this variant, the size of the source region 101 in each first type micro cell 131 is increased compared to the variant of FIG. 4. Furthermore, FIG. 8 illustrated one feature of the above described embodiments, according to which a portion of the trench grid structure is filled with the isolating material 143 instead of electrode material.

Of course, the illustration in FIGS. 8(A) and (B) is only schematic and exemplary; depending on the designated characteristic of the device 1, the portions and positions of the trench grid structure including the isolating material 143 may be varied. E.g., the isolating material 143 could also be deposited at the bottom region of the trench grid structure 13, e.g., before filling the trench grid structure with the electrode material for forming the trench control electrode 141.

Presented herein is also a method of producing a power semiconductor device. For example, the method of producing a power semiconductor device comprises forming the following components: a semiconductor body with a drift region of a first conductivity type; a first load terminal at a first side of the semiconductor body; a second load terminal at a second side of the semiconductor body opposite to the first side, wherein the power semiconductor device is configured to conduct a forward load current between the first load terminal and the second load terminal; a trench grid structure extending from the first side into the semiconductor body, wherein the trench grid structure comprises a plurality of macro cells, each macro cell comprising at least one first type micro cell configured for the forward load current conduction and a number of second type micro cells not configured for the forward load current conduction. Each of the first type micro cells and the second type micro cells is laterally confined by a respective portion of the trench grid structure. In each of the macro cells, the number of the second type micro cells is equal to or greater than the number of first type micro cells.

Embodiments of the above-described method correspond to the embodiments of the power semiconductor device 1 described above. Accordingly, these embodiments of the method will not literally be described herein, but it is referred to the above.

E.g., as indicated above, the proposed trench grid structure allows for a comparatively low complex manufacturing procedure, e.g., since no source trenches or other trenches need to be contacted, in accordance with an embodiment. Furthermore, in an embodiment, only a gate runner in the edge termination region 1-3 is needed to electrically contact the control electrodes 141 in the trench structure 13. For example, the control electrodes 141 are uninterruptedly connected with each other across the macro cells 130. Thereby, gate fingers (or other structures) extending into the active region 1-2 to contact the control electrodes 141 there can be avoided, and the processing complexity for producing the power semiconductor device 1 is correspondingly low.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1−x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

What is claimed is:

1. A power semiconductor device, comprising:
a semiconductor body with a drift region of a first conductivity type;
a first load terminal at a first side of the semiconductor body;
a second load terminal at a second side of the semiconductor body opposite to the first side, wherein the power semiconductor device is configured to conduct a forward load current between the first load terminal and the second load terminal;
a trench grid structure extending from the first side into the semiconductor body,
wherein the trench grid structure comprises a plurality of macro cells, each macro cell comprising at least one first type micro cell configured for the forward load current conduction and a number of second type micro cells not configured for the forward load current conduction,
wherein each of the first type micro cells and the second type micro cells is laterally confined by a respective portion of the trench grid structure,
wherein in each of the macro cells, the number of the second type micro cells is equal to or greater than the number of first type micro cells.

2. The power semiconductor device of claim 1, wherein the trench grid structure houses a trench control electrode and a trench insulator electrically insulating the trench control electrode from the semiconductor body.

3. The power semiconductor device of claim 2, wherein at least each first type micro cell is surrounded by a portion of the trench control electrode.

4. The power semiconductor device of claim 2, wherein the trench control electrode is configured to induce, upon being subjected with a control signal, an inversion channel within each of the first type micro cells.

5. The power semiconductor device of claim 2, wherein the trench grid structure exclusively houses the trench control electrode, and wherein the trench control electrode forms an uninterrupted electrically conductive structure within the trench grid structure.

6. The power semiconductor device of claim 1, wherein each of the first type micro cells is electrically connected with the first load terminal.

7. The power semiconductor device of claim 1, wherein each of the first type micro cells includes a semiconductor source region of the first conductivity type and a semiconductor body region of the second conductivity type, wherein the semiconductor body region isolates the semiconductor source region from the drift region, and wherein both the semiconductor source region and the semiconductor body region are electrically connected to the first load terminal.

8. The power semiconductor device of claim 1, wherein each of the second type micro cells is devoid of a region of the first conductivity type electrically connected to the first load terminal.

9. The power semiconductor device of claim 1, wherein each of the first type micro cells exhibits a rectangular horizontal cross-sectional area having side faces, with an aspect ratio among the side faces of at most 2:1.

10. The power semiconductor device of claim 1, wherein each of the macro cells, each of the first type micro cells, and each of the second type micro cells exhibits a rectangular horizontal cross-sectional area.

11. The power semiconductor device of claim 1, wherein each of the first type micro cells exhibits a horizontal cross-sectional area of smaller than 5 μm*5 μm.

12. The power semiconductor device of claim 1, wherein in each of the macro cells, the at least one of the first type micro cells exhibits a horizontal cross-sectional area smaller than each horizontal cross-sectional area of the second type micro cells.

13. The power semiconductor device of claim 1, wherein in each of the macro cells, the at least one first type micro cell is surrounded by the second type micro cells.

14. The power semiconductor device of claim 1, wherein in each of the macro cells, a ratio of the number of the second type micro cells to the number of first type micro cells is at least 3/1.

15. The power semiconductor device of claim 1, wherein the trench grid structure exhibits a constant depth along a vertical direction, the constant depth locally varying by less than 1 μm.

16. The power semiconductor device of claim 1, wherein portions of the trench grid structure are filled with an isolating material.

17. The power semiconductor device of claim 1, wherein each of the first type micro cells exhibits a quadratic horizontal cross-sectional area.

18. The power semiconductor device of claim 1, wherein each of one or more of the first type micro cells is surrounded by a semiconductor source region of the first conductivity type within the respective first type micro cell.

19. The power semiconductor device of claim 1, wherein the semiconductor body region exhibits, within the macro cells, a depth of less than 50% of the depth of the trench grid structure.

20. A method of producing a power semiconductor device, the method comprising:
forming a semiconductor body with a drift region of a first conductivity type;
forming a first load terminal at a first side of the semiconductor body;
forming a second load terminal at a second side of the semiconductor body opposite to the first side, wherein the power semiconductor device is configured to conduct a forward load current between the first load terminal and the second load terminal;
forming a trench grid structure extending from the first side into the semiconductor body, wherein the trench grid structure comprises a plurality of macro cells, each macro cell comprising at least one first type micro cell configured for the forward load current conduction and a number of second type micro cells not configured for the forward load current conduction,
wherein: each of the first type micro cells and the second type micro cells is laterally confined by a respective portion of the trench grid structure,
wherein in each of the macro cells, the number of the second type micro cells is equal to or greater than the number of first type micro cells.
